(19) United States
(12) Patent Application Publication
(10) Pub. No.: US 2020/0168490 A1
(43) Pub. Date: May 28, 2020

(54) SCANNING ALIGNMENT DEVICE AND SCANNING METHOD THEREFOR

(71) Applicant: SHANGHAI MICRO ELECTRONICS EQUIPMENT (GROUP) CO., LTD., Shanghai (CN)

(72) Inventors: Dawei YU, Shanghai (CN); Shihua WANG, Shanghai (CN); Dongliang HUANG, Shanghai (CN)

(21) Appl. No.: 16/632,307

(22) PCT Filed: Jul. 17, 2018
(86) PCT No.: PCT/CN2018/095896

§ 371 Date: Jan. 17, 2020

(30) Foreign Application Priority Data
Jul. 17, 2017 (CN) 201710582793.6

(51) Int. Cl. H01L 21/67; H04N 5/225

(52) U.S. Cl. CPC H01L 21/67259; H04N 5/2254; H04N 5/2253

(57) ABSTRACT

A scanning alignment apparatus and scanning methods thereof are disclosed. The scanning alignment apparatus is used to scan a substrate and includes a transflective lens unit, an imaging element unit, an alignment lens unit and an illumination lens unit. The alignment lens unit includes a plurality of sub-alignment lens units, and the imaging element unit includes a plurality of imaging elements. Each of the sub-alignment lens units corresponds to a respective one of the imaging elements. The scanning alignment apparatus and scanning methods provided in the present invention can achieve higher scanning efficiency and thus enhanced productivity and product throughput.

### TECHNICAL FIELD

The present invention relates to the field of semiconductor fabrication and, in particular, to a scanning alignment apparatus and scanning methods thereof.

### BACKGROUND

Fan-out is an important process in the fabrication of integrated circuit chips. As shown in FIG. 1, a conventional fan-out process includes the steps of:

step 1) uniformly placing a plurality of dies 101 on a substrate 102, with their front sides facing upward;

step 2) encapsulating the dies 101 with a resin 103 and curing the resin;

step 3) removing the substrate 102 so that back sides of the dies 101 are exposed and flipping over the resin sheet encapsulating the dies so that the back sides of the dies 101 face upward;

step 4) forming a redistribution layer 104 by performing photolithography, electroplating, and etching processes (i.e., the redistribution layer is formed by depositing a metal layer and a dielectric layer over the surface of the resin sheet encapsulating the dies and forming the metal wiring patterns on the dies);

step 5) forming a passivation layer 105 (i.e., a protective dielectric film formed over the redistribution layer to prevent the redistribution layer from being corroded);

step 6) forming, in the passivation layer 105, solder balls 106 in contact with the redistribution layer 104, wherein metal bumps may be formed instead using a bumping technique; and

step 7) after performing a test, the structure obtained from step 6) is diced into a plurality of individual devices 107, each device 107 containing at least one of the dies 101.

However, the step supposed to uniformly place the dies 101 on the substrate 102 is often associated with the issues of large deviations from the target positions for the dies 101. As shown in FIG. 2, although the dies 101 are intended to be arranged on a line 201, the dies 101 may be actually placed on another line 202. However, the line 201 is deviated from another line 202 by up to 10 μm, exceeding the tolerance of an involved process (e.g., overlay tolerance) that is 4 μm. For this reason, it is necessary to correct the positions of the dies 101 prior to the next process (e.g., exposure).

During the process of correcting the position of the dies 101, the dies 101 are first scanned in order to obtain the positional information of the dies 101. Conventional apparatuses for such scanning alignment employ only one imaging element capable of scanning the dies 101 in an associated scanning field-of-view (FOV), from which positional information of the dies 101 can be extracted and then recorded. Therefore, this approach is inefficient and tends to lead to low productivity and low product throughput.

### SUMMARY OF THE INVENTION

It is an objective of the present invention to overcome the above-described problems of low scanning efficiency, low productivity and low product throughput arising from the use of conventional alignment apparatuses by providing a novel scanning alignment apparatus and scanning methods thereof.

To this end, the provided scanning alignment apparatus is used to scan a substrate and includes a transflective lens unit, an imaging element unit, an alignment lens unit and an illumination lens unit. The alignment lens unit includes a plurality of sub-alignment lens units, and the imaging element unit includes a plurality of imaging elements. Each of the sub-alignment lens units corresponds to a respective one of the imaging elements.

Optionally, the sub-alignment lens units in the alignment lens unit may be arranged along a first direction, wherein the imaging elements in the imaging element unit are arranged along the first direction, wherein the transflective lens unit, imaging element unit and alignment lens unit are arranged along a second direction, wherein the transflective lens unit is arranged side by side with respect to the illumination lens unit along a third direction, and wherein the second direction is perpendicular to the first direction and inclined relative to the third direction at an angle.

Optionally, the alignment lens unit may include a first sub-alignment lens unit and a second sub-alignment lens unit, wherein the first sub-alignment lens unit is disposed between the imaging element unit and the transflective lens unit and the second sub-alignment lens unit is disposed between the first sub-alignment lens unit and the transflective lens unit or between the transflective lens unit and the substrate.

Optionally, light may be incident on the transflective lens unit along a direction that is inclined at an angle of 45° relative to a direction in which the transflective lens unit is disposed.

Optionally, the alignment lens unit may be configured to split a light beam passing therethrough into a plurality of sub-beams, wherein the imaging element unit is configured to obtain an image of the substrate from the plurality of sub-beams.

Optionally, the imaging elements may be charge-coupled devices each acting on a respective one of the sub-beams.

Optionally, the imaging elements may have distinctly different magnifications, which exhibit a progressively decreasing magnification profile.

Optionally, the transflective lens unit may include one transflective member or a plurality of transflective elements arranged along the first direction.

Optionally, the illumination lens unit may include one illumination lens or a plurality of illumination lens elements arranged along the first direction.

Optionally, the illumination lens or illumination lens elements may be cylindrical or Fresnel lens(es).

The present invention also provides a scanning method using the scanning alignment apparatus as defined above, wherein the alignment lens unit is configured to split a light beam passing therethrough into a plurality of sub-beams, which create respective partial scanning field-of-views (FOVs) together providing a scanning FOV defined by a first scanning direction and a second scanning direction perpendicular to the first scanning direction. The scanning method includes the steps of:

(1) moving the scanning alignment apparatus to an initial position and aligning its first direction with the second scanning direction of the substrate;

(2) moving the scanning alignment apparatus a first distance in the first scanning direction while causing it to perform a scan on the substrate;

(3) moving the scanning alignment apparatus a second distance in the second scanning direction;

(4) moving the scanning alignment apparatus the first distance in a direction opposite to the first scanning direction while causing it to perform another scan on the substrate;

(5) moving the scanning alignment apparatus the second distance in the second scanning direction; and

(6) repeating steps 2 to 5 until an aggregate scanned width of the scans performed in the repetitions is greater than or equal to a maximum size of the substrate in the second scanning direction,

wherein the first distance is greater than or equal to a maximum size of the substrate in the first scanning direction and the second distance is equal to a width of the scanning FOV measured in a direction parallel to the first direction.

Optionally, there may be gaps between the partial scanning FOVs, which have a width smaller than a width of the partial scanning FOVs, wherein the scanning method further includes the step of:

(7) moving the scanning alignment apparatus back to the initial position in step 1 and then a third distance in the second scanning direction and repeating steps 2 to 6,

wherein the third distance is greater than the width of the gaps between the partial scanning FOVs and smaller than the width of the partial scanning FOVs.

The present invention also provides another scanning method using the scanning alignment apparatus as defined above, wherein the alignment lens unit is configured to split a light beam passing therethrough into a plurality of sub-beams, which create respective partial scanning FOVs together providing a scanning FOV. The scanning method includes the steps of:

(1) moving the scanning alignment apparatus to an initial position and aligning its first direction with a radial direction of the substrate; and

(2) rotating the substrate or the scanning alignment apparatus at least one revolution about a vertical axis of the substrate, concurrently with the scanning alignment apparatus scanning the substrate.

Optionally, there may be gaps between the partial scanning FOVs, which have a width smaller than a width of the partial scanning FOVs, wherein the scanning method further includes the steps of:

(3) moving the scanning alignment apparatus back to the initial position in step 1 and then a fourth distance in the radial direction of the substrate; and

(4) rotating the substrate or the scanning alignment apparatus at least one revolution about the vertical axis of the substrate, concurrently with the scanning alignment apparatus scanning the substrate,

wherein the fourth distance is greater than the width of the gaps between the partial scanning FOVs and smaller than the width of the partial scanning FOVs.

In summary, compared to the conventional approach, the scanning alignment apparatus and scanning methods provided in the present invention employs more imaging elements which can provide the same greater number of scanning FOVs. As a result, an expanded aggregate scanning FOV can be obtained, resulting in increased scanning efficiency, higher productivity and higher product throughput.

### BRIEF DESCRIPTION OF THE DRAWINGS

FIG. 1 is a flowchart graphically illustrating a conventional fan-out process.

FIG. 2 is a diagram schematically illustrating the placement of dies on a substrate in the conventional process.

FIG. 3 schematically illustrates how a scanning alignment apparatus according to an embodiment of the present invention receives incident light and directs onto a substrate.

FIG. 4 schematically illustrates how a scanning alignment apparatus according to another embodiment of the invention receives incident light and directs onto a substrate.

FIGS. 5 and 6 are schematic illustrations of a scan path along which a scanning alignment apparatus scans a substrate in a scanning method according to an embodiment of the invention.

FIG. 7 schematically illustrates a scanning field-of-view (FOV) formed by a scanning alignment apparatus on a substrate in another scanning method according to another embodiment of the invention.

FIG. 8 shows a relationship between magnifications of a plurality of imaging elements according to an embodiment of the invention and their distances from a center of a substrate.

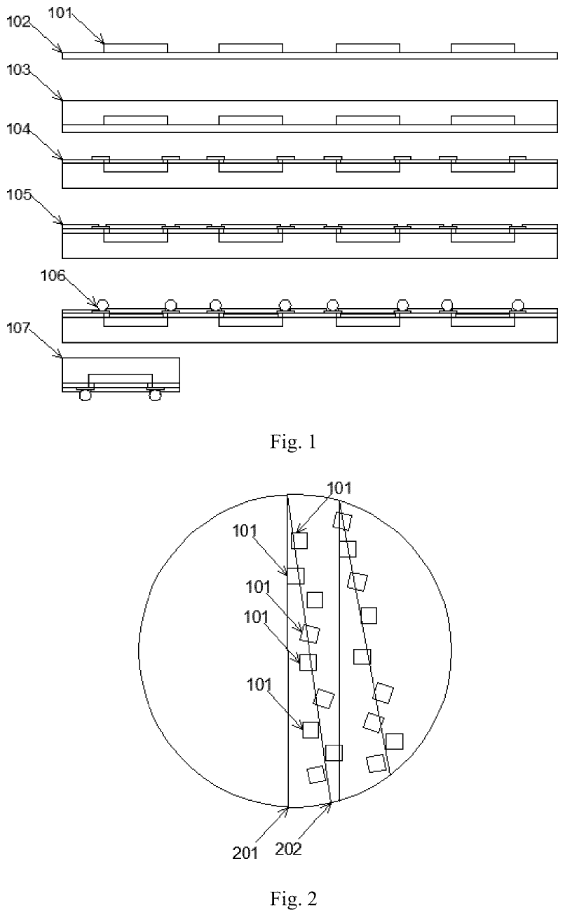

In these figures,

100, 200-scanning alignment apparatus;

101-die; 102, 307-substrate; 103-resin; 104-redistribution layer; 105-passivation layer;

106-solder ball; 107-individual device; 201-line; 202-another line; 301-transflective lens unit;

3011, 3012, 3013-sub-transflective lens; 302-imaging element unit;

3021, 3022, 3023-imaging element; 303-first sub-alignment lens unit;

3031, 3032, 3033, 3041, 3042, 3043-sub-alignment lens; 304-second sub-alignment lens unit;

305-illumination lens; 3051, 3052, 3053-sub-illumination lens; 306-incident light beam; 307-substrate;

401-scanning field-of-view (FOV).

### DETAILED DESCRIPTION

Specific embodiments of the present invention will be described in greater detail below with reference to the annexed schematic diagrams. Features and advantages of the invention will be more apparent from the following detailed description, and from the appended claims. Note that the accompanying drawings are provided in a very simplified form not necessarily presented to exact scale, with their only intention to facilitate convenience and clarity in explaining the embodiments.

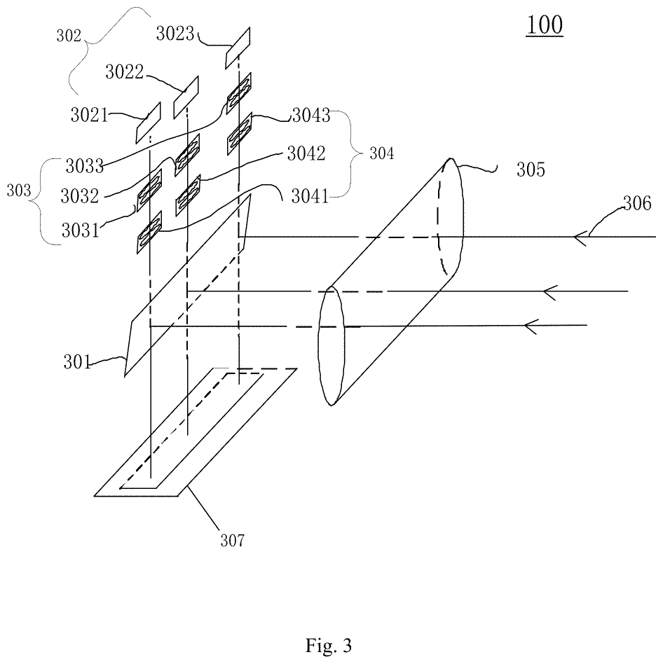

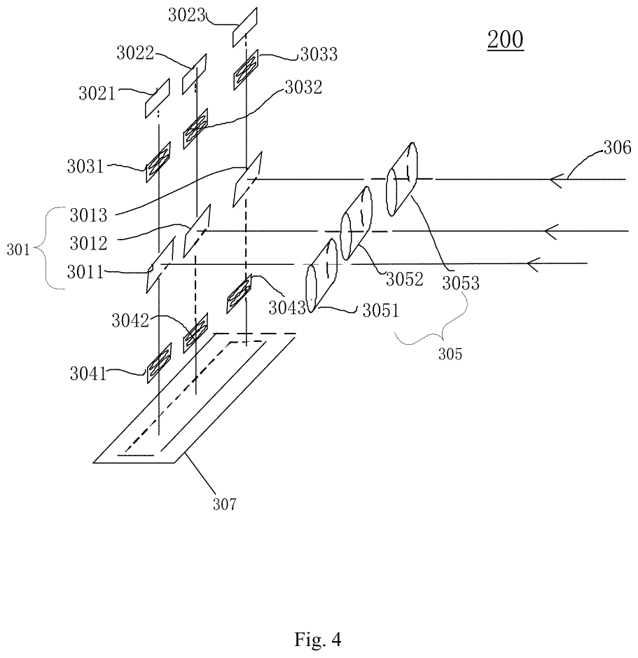

Referring to FIGS. 3 and 4, the scanning alignment apparatus includes a transflective lens unit, an imaging element unit 302, an alignment lens unit and an illumination lens unit. The alignment lens unit includes a plurality of sub-alignment lens units including, for example, a first sub-alignment lens unit 303 and a second sub-alignment lens unit 304. The imaging element unit 302 includes a plurality of imaging elements, each corresponding to a respective one of the plurality of sub-alignment lens units. The transflective lens unit includes one transflective lens or a plurality of sub-transflective lenses, and the illumination lens unit includes one illumination lens or a plurality of sub-illumination lenses.

In the example shown in FIG. 3, the transflective lens unit includes one transflective lens, and the illumination lens unit includes one illumination lens. In the example of FIG. 4, the transflective lens unit includes a plurality of sub-transflective lenses 3011, 3012, 3013, and the illumination lens unit includes a plurality of sub-illumination lenses 3051, 3052, 3053.

In practical use, an incident light beam 306 is transformed by the illumination lens unit into a single continuous light beam incident on the transflective lens unit, which then reflects the incident continuous light beam onto a substrate 307. Light reflected from the substrate 307 propagates through the transflective lens unit and reaches the alignment lens unit, where it is split into a plurality of sub-beams. These sub-beams are then incident on the imaging element unit 302, thus forming an image of the substrate. Each of the sub-beams is incident on a respective one of the imaging elements.

FIG. 3 schematically illustrates how a scanning alignment apparatus 100 according to an embodiment of the present invention receives incident light and directs the incident light onto a substrate. As shown in FIG. 3, the transflective lens unit 301 in the scanning alignment apparatus 100 is implemented as one transflective lens and the illumination lens unit 305 as one illumination lens. Additionally, the alignment lens unit includes a first sub-alignment lens unit 303 and a second sub-alignment lens unit 304, each of the first sub-alignment lens unit 303 and the second sub-alignment lens unit 304 includes a plurality of sub-alignment lenses arranged along a first direction. The imaging element unit 302 includes a plurality of imaging elements 3021, 3022, 3023 also arranged along the first direction.

According to one embodiment, the imaging element unit 302, the first sub-alignment lens unit 303, the second sub-alignment lens unit 304 and the transflective lens unit 301 are arranged sequentially in this order along a second direction. In addition, the transflective lens unit 301 is arranged side by side with respect to the illumination lens 305 along a third direction. The second direction is perpendicular to the first direction and inclined with respect to the third direction at an angle ranging from 0° to 180°, preferably 90°. This angle can ensure that the incident light is perpendicularly incident on the substrate after passing through the transflective lens unit 301 and follows the same way back to the transflective lens unit 301 so that it can transmit through the transflective lens unit 301. In addition, the incident light propagates in different directions before and after the transmission, effectively ensuring component design and assembly. As shown in FIG. 3, the direction in which the incident light propagates before the transmission is the third direction. Before reaching the transflective lens, it may experience shaping, so its path may be curved or bent rather than necessarily being straight. The second direction is perpendicular to the plane in which the substrate 307 is disposed. The first direction is perpendicular to both the direction in which the incident light propagates before the transmission and the second direction.

The first sub-alignment lens unit 303 may include, but not limited to, three sub-alignment lenses 3031, 3032, 3033. It would be appreciated that the number of the sub-alignment lenses in the first sub-alignment lens unit 303 may be increased or decreased, as desired.

The second sub-alignment lens unit 304 may include, but not limited to, three sub-alignment lenses 3041, 3042, 3043. It would be appreciated that the number of the sub-alignment lenses in the second sub-alignment lens unit 304 may be increased or decreased, as desired.

The imaging element unit 302 may include, but not limited to, three imaging elements 3021, 3022, 3023. The number of the imaging elements in the sub-alignment lenses may be accordingly increased or decreased with the number of the sub-alignment lenses, imparting structural flexibility to the scanning alignment apparatus 100. In one embodiment, the number of the imaging elements is the same as the number of the sub-alignment lenses in the first sub-alignment lens unit.

In practical use, an incident light beam 306 is transformed by the illumination lens 305 into a single continuous light beam incident on the transflective lens unit 301, the transflective lens unit 301 then reflects the incident continuous light beam onto the substrate 307. Light reflected from the substrate 307 propagates through the transflective lens unit 301 and then successively through the second sub-alignment lens unit 304 and the first sub-alignment lens unit 303. As a result, the light after passing through the second sub-alignment lens unit 304 and the first sub-alignment lens unit 303 is split into a plurality of sub-beams, which are subsequently incident on the imaging element unit 302, forming an image of the substrate on the imaging element unit 302. Each of the sub-beams is incident on a respective one of the imaging elements.

Differing from the case shown in FIG. 3, where the first and second sub-alignment lens units 303, 304 are disposed between the imaging element unit 302 and the transflective lens unit 301, in another embodiment as shown in FIG. 4, scanning alignment apparatus 200 receives incident light and directs it onto the substrate. As shown in FIG. 4, the second sub-alignment lens unit 3041, 3042, 3043 is disposed between the transflective lens unit and the substrate 307.

Additionally, in the embodiment of FIG. 4, the transflective lens unit 301 of FIG. 3 is divided into a plurality of sub-transflective lenses which are aligned along the first direction. The sub-transflective lenses include, but are not limited to, three sub-transflective lenses 3011, 3012, 3013, and the number of the sub-transflective lenses may be increased or decreased, as desired. Further, in the embodiment as shown in FIG. 4, the illumination lens 305 in FIG. 3 are divided into a plurality of sub-illumination lenses which are also aligned along the first direction. The sub-illumination lenses include, but are not limited to, three sub-illumination lenses 3051, 3052, 3053, and the number of the sub-illumination lenses may be increased or decreased as desired.

In the embodiments of FIGS. 3 and 4, the one or more illumination lenses may be cylindrical lens or Fresnel lenses. In case of the single transflective lens, its direction of light incidence may be inclined at an angle of 45° with respect to a direction in which it is disposed. The imaging element may be particularly charge-coupled devices each acting on a respective one of the sub-beams.

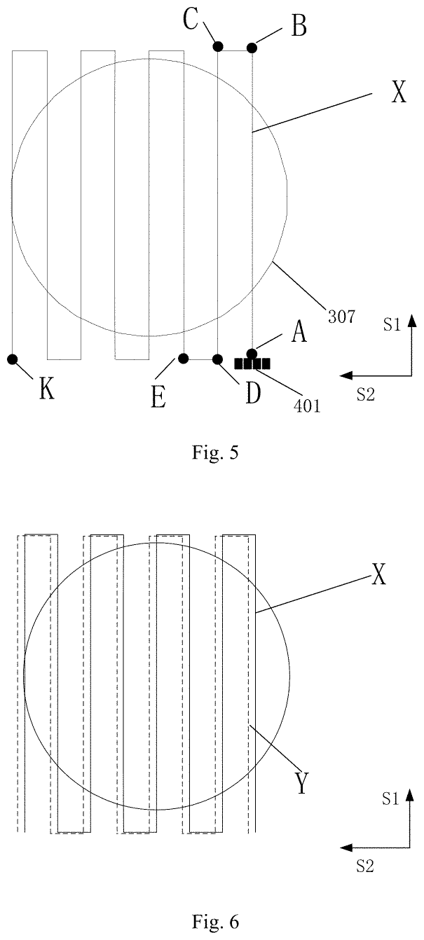

Furthermore, FIG. 5 is a schematic illustration of a scan path along which a scanning alignment apparatus scans a substrate in a scanning method according to an embodiment of the invention. The scanning alignment apparatus may be, without implying any limitation, either the above-described scanning alignment apparatus 100 or the scanning alignment apparatus 200. Each of the sub-beams corresponds to a respective partial scanning field-of-view (FOV). All the partial scanning FOVs constitute a scanning FOV.

As shown in FIG. 5, the scanning FOV resulting from the partial scanning FOVs has a scanning width, and the scanning method using the scanning alignment apparatus will be described in detail below.

When there is no gap between the partial scanning FOVs, the method may include the steps of:

step 1) moving the scanning FOV 401 of the scanning alignment apparatus to point A,

step 2) moving the scanning alignment apparatus a first distance in a first scanning direction S1 along the path X to point B;

step 3) moving the scanning alignment apparatus a second distance in a second scanning direction S2 perpendicular to the first scanning direction S1 along the path X to point C;

step 4) moving the scanning alignment apparatus the first distance in a direction opposite to the first scanning direction Si along the path X to point D; and

step 5) moving the scanning alignment apparatus the second distance in the second scanning direction S2 along the path X to point E.

With these steps as one cycle, the scanning of the substrate can be completed when the distance from the starting point A to an end point K is greater than or equal to a diameter of the substrate 307.

In order to ensure that the whole substrate is scanned, the first distance is greater than or equal to the diameter of the substrate 307 (not limited thereto), and the second distance is equal to a width of the scanning FOV 401.

When there are gaps between the partial scanning FOVs, the method may further include: planning a path Y that is identical to the path X and deviated therefrom in the second scanning direction by a third distance (referring to FIG. 6). The third distance is greater than the gaps between, and smaller than a width of, the partial scanning FOVs. In this case, after the scan along the path X, another scan can be performed along the path Y deviated therefrom by the third distance. In this way, scanning of the whole substrate can be ensured.

According to this embodiment, the scans can be performed by moving either of the scanning alignment apparatus and the substrate 307 along the paths X and Y.

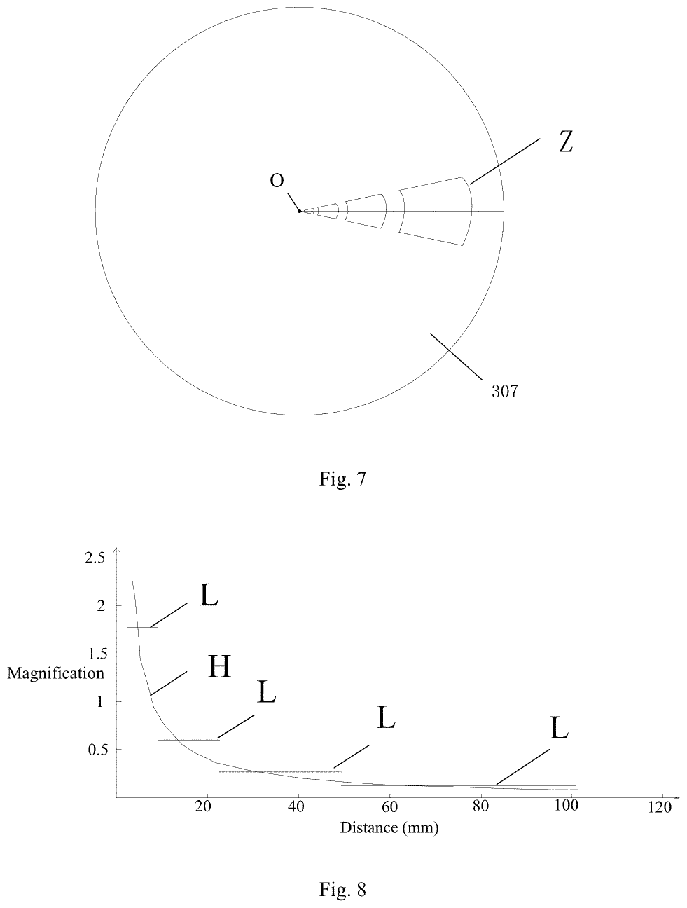

FIG. 7 schematically illustrates a scanning FOV formed by a scanning alignment apparatus on a substrate in another scanning method according to an embodiment of the invention. In the case shown in FIG. 7, the imaging element unit 302 of the scanning alignment apparatus includes four imaging elements, the magnification of each of the four imaging elements in the imaging element unit 302 progressively decreases in the direction pointing radially from the substrate's center O to its edge. As a result, partial scanning FOVs with size gradually increasing in said direction from the center O to the edge are formed and together form a substantially fan-shaped scanning FOV Z on the substrate. FIG. 8 shows a relationship between the magnification of the imaging elements and their distance from the center O.

In FIG. 8, the horizontal axis represents the imaging elements' radial distance from the center O of the substrate 305, measured in mm, and the vertical axis presents their magnification. In FIG. 8, compared with an ideal magnification profile indicated at H, since the imaging elements each have has a certain width in the radial direction of the substrate 305 and a fixed magnification factor, the actual profile is stepped lines corresponding to the respective partial scanning FOVs as in FIG. 7. In practical scanning applications, it is also possible to enable three of the four imaging elements. In this case, three partial scanning FOVs will be formed on the substrate, and accordingly, three corresponding stepped lines will appear in FIG. 8. Those of ordinary skill in the art would appreciate that the invention is not limited to four or three imaging elements, because different numbers of imaging elements can be employed to satisfy the requirements of various actual scanning applications.

The other scanning method using the above scanning alignment apparatus will be detailed below with reference to FIG. 7.

When there is no gap between the imaging elements, the method may include the steps of:

step 11) moving the scanning alignment apparatus to an initial position and tuning its first direction into coincidence with the substrate's radial direction so that the scanning FOV resulting from the partial scanning FOVs of the imaging elements covers at least part of the substrate's radius; and

step 12) rotating the substrate 305 about a normal of the substrate 305 passing through the center O rotated at least one revolution, concurrently with the imaging element unit 302 scanning the substrate 305.

Preferably, at the initial position, the scanning FOV resulting from the partial scanning FOVs of the imaging elements covers the entire radius of the substrate so that step 12) is allowed to be performed only once.

Optionally, when the scanning FOV of the scanning alignment apparatus at the initial position does not cover the entire radius of the substrate, step 12) may be performed several times from different initial positions to complete the scanning of the whole substrate. It would be readily appreciated that, if the scanning FOV of the scanning alignment apparatus at the initial position encompasses the substrate's center O, step 12) allows the scanning of a circular area of the substrate encompassing the center O; otherwise, it allows the scanning of an annular area of the substrate.

Furthermore, when there are gaps between the partial scanning FOVs, which are narrower than the partial scanning FOVs, in the scanning method, subsequent to the completion of step 12), the initial position of the scanning alignment apparatus may be shifted a fourth distance toward the center O, followed by repeating step 12) for another time. The fourth distance may be greater than the width of the gaps between the partial scanning FOVs and smaller than that of the partial scanning FOVs themselves. In this way, the scanning of the whole substrate 305 can be still achieved.

The imaging elements in the above embodiment may be charge-coupled devices with distinctly different magnifications. It would be appreciated that the scanning FOV is a range of scanning defined by the incident light 306 that is projected by the scanning alignment apparatus onto the substrate 305 and fed back to the imaging element unit 302, while each of the partial scanning FOVs is a range of scanning defined by part of the incident light 306 that is projected by the scanning alignment apparatus onto the substrate 305 and fed back to a respective one of the imaging elements.

In summary, in the scanning alignment apparatus of the present invention, an incident light beam is transformed by the illumination lens unit into a single continuous light beam incident on the transflective lens unit, which then reflects the incident continuous light beam onto a substrate. The first and second sub-alignment lens units are configured to split the light beam passing therethrough into a plurality of sub-beams, while the imaging element unit is configured to obtain an image of the substrate from the plurality of sub-beams. Compared to the conventional approach, the invention employs more imaging elements which can provide the same greater number of scanning FOVs. As a result, an expanded aggregate scanning FOV can be obtained, resulting in increased scanning efficiency, higher productivity and higher product throughput.

The embodiments presented above are merely several preferred examples and are in no way meant to limit the present invention. It is intended that any modifications such as equivalent alternatives or variations made to the subject matter or features thereof disclosed herein made by any person of ordinary skill in the art based on the above teachings without departing from the scope of the present invention are also considered to fall within the scope of the present invention.

1. A scanning alignment apparatus for scanning a substrate, comprising a transflective lens unit, an imaging element unit, an alignment lens unit and an illumination lens unit, the alignment lens unit comprising a plurality of sub-alignment lens units, the imaging element unit comprising a plurality of imaging elements, wherein each of the plurality of sub-alignment lens units corresponds to a respective one of the plurality of imaging elements.

2. The scanning alignment apparatus of claim 1, wherein the plurality of sub-alignment lens units in the alignment lens unit are arranged along a first direction, wherein the plurality of imaging elements in the imaging element unit are arranged along the first direction, wherein the transflective lens unit, the imaging element unit and the alignment lens unit are arranged along a second direction, wherein the transflective lens unit and the illumination lens unit are arranged along a third direction, and wherein the second direction is perpendicular to the first direction and inclined relative to the third direction at an angle.

3. The scanning alignment apparatus of claim 1, wherein the alignment lens unit comprises a first sub-alignment lens unit and a second sub-alignment lens unit, the first sub-alignment lens unit disposed between the imaging element unit and the transflective lens unit, and
wherein the second sub-alignment lens unit is disposed between the first sub-alignment lens unit and the transflective lens unit, or between the transflective lens unit and the substrate.

4. The scanning alignment apparatus of claim 1, wherein light is incident on the transflective lens unit along a direction that is inclined at an angle of 45° relative to a direction in which the transflective lens unit is disposed.

5. The scanning alignment apparatus of claim 1, wherein the alignment lens unit is configured to split a beam passing therethrough into a plurality of sub-beams, and wherein the imaging element unit is configured to obtain an image of the substrate from the plurality of sub-beams.

6. The scanning alignment apparatus of claim 5, wherein the plurality of imaging elements are charge-coupled devices each configured to form an image of a corresponding one of the plurality of sub-beams.

7. The scanning alignment apparatus of claim 1, wherein the plurality of imaging elements have distinctly different magnifications which sequentially decrease.

8. The scanning alignment apparatus of claim 1, wherein the transflective lens unit comprises one transflective lens or a plurality of sub-transflective lenses arranged along the first direction.

9. The scanning alignment apparatus of claim 1, wherein the illumination lens unit comprises one illumination lens or a plurality of sub-illumination lenses arranged along the first direction.

10. The scanning alignment apparatus of claim 9, wherein the illumination lens or each of the sub-illumination lenses is a cylindrical or Fresnel lens.

11. A scanning method using the scanning alignment apparatus of claim 1, wherein the alignment lens unit is configured to split a beam passing therethrough into a plurality of sub-beams, each corresponding to one of a plurality of partial scanning field-of-views (FOVs) which constitute together a scanning FOV defined by a first scanning direction and a second scanning direction perpendicular to the first scanning direction, and wherein the scanning method comprises the steps of:
1) aligning a first direction of the scanning alignment apparatus with the second scanning direction of the substrate and positioning the scanning alignment apparatus at an initial location;
2) moving the scanning alignment apparatus a first distance in the first scanning direction to perform a scan on the substrate;
3) moving the scanning alignment apparatus a second distance in the second scanning direction;
4) moving the scanning alignment apparatus the first distance in a direction opposite to the first scanning direction to perform another scan on the substrate;
5) moving the scanning alignment apparatus the second distance in the second scanning direction; and
6) repeating steps 2) to 5) until an aggregate scanned width of the scans is greater than or equal to a maximum size of the substrate in the second scanning direction,
wherein the first distance is greater than or equal to a maximum size of the substrate in the first scanning direction and the second distance is equal to a width of the scanning FOV measured in a direction parallel to the first direction.

12. The scanning method of claim 11, wherein there are gaps between the partial scanning FOVs, each of the gaps having a width smaller than a width of each of the partial scanning FOVs, and wherein the scanning method further comprises the step of:
7) returning the scanning alignment apparatus to the initial location in step 1), moving a third distance in the second scanning direction, and then repeating steps 2) to 6), wherein the third distance is greater than the gap between the partial scanning FOVs and smaller than the width of the partial scanning FOV.

13. A scanning method using the scanning alignment apparatus of claim 1, wherein the alignment lens unit is configured to split a light beam passing therethrough into a plurality of sub-beams, each corresponding to one of a plurality of partial scanning field-of-views (FOVs) which constitute together a scanning FOV, and wherein the scanning method comprises the steps of:
1) aligning a first direction of the scanning alignment apparatus with a radial direction of the substrate and positioning the scanning alignment apparatus at an initial location; and
2) rotating the substrate or the scanning alignment apparatus for at least one round about a vertical axis of the substrate and scanning.

14. The scanning method of claim 13, wherein there are gaps between the partial scanning FOVs, each of the gaps having a width smaller than a width of each of the partial scanning FOVs, and wherein the scanning method further comprises the steps of:
3) returning the scanning alignment apparatus to the initial location in step 1) and then moving a fourth distance in the radial direction of the substrate; and
4) rotating the substrate or the scanning alignment apparatus for at least one round about the vertical axis of the substrate and scanning,
wherein the fourth distance is greater than the gap between the partial scanning FOVs and smaller than the width of the partial scanning FOV.
